(19) United States
(12) Patent Application Publication
(10) Pub. No.: US 2020/0199738 A1
(43) Pub. Date: Jun. 25, 2020

(54) EVAPORATION DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Liang CHEN, Wuhan, Hubei (CN)

(21) Appl. No.: 16/347,884

(22) PCT Filed: Dec. 24, 2018
(86) PCT No.: PCT/CN2018/123149

§ 371 Date: May 7, 2019

(30) Foreign Application Priority Data
Nov. 26, 2018 (CN) 201811420289.7

(51) Int. Cl. C23C 14/24; C23C 14/26; C23C 14/54

(52) U.S. Cl. CPC C23C 14/243; C23C 14/54; C23C 14/26

(57) ABSTRACT

An evaporation device includes an evaporator, a gas chamber, pipelines, a heating unit, and a controller. The evaporator is used for containing and vaporing an evaporation material. The gas chamber is used for collecting vapor from the evaporation material, and nozzles are disposed at an interval and on a side face of the gas chamber. The pipelines are disposed between the evaporator and the gas chamber, and two ends of each pipeline communicate with the evaporator and the gas chamber respectively. The heating unit is disposed at peripheries of the evaporator, the gas chamber, and the pipelines and configured to heat the evaporator, the gas chamber, and the pipelines. The controller is electrically connected to the heating unit and configured to control a temperature of the heating unit in order that the temperature and pressure inside the gas chamber retain predetermined values respectively.

### BACKGROUND OF DISCLOSURE

### 1. Field of Disclosure

The present disclosure relates to the field of evaporation technology, and more particularly, to an evaporation device.

### 2. Description of Related Art

In the production of organic light-emitting diode (OLED) panels, organic materials are required to vapor in an evaporation source of an evaporation equipment, and the forming vapor is sprayed on a substrate above the evaporation equipment through nozzles of the evaporation source and then condenses on a surface of the substrate so as to realize an evaporation process.

As shown in FIG. 1, which is a schematic structural diagram of a conventional evaporation device. An evaporation device 1 includes an evaporator 20 used for containing and vaporing organic materials. Several nozzles 12 are disposed on the top of the evaporator 20. When proceeding in a normal evaporation process, the evaporator 20 is heated by a heater (not shown), an evaporation material in the evaporator 20 is heated and vapored into gas, and the gas is sprayed on a substrate (not shown) through the nozzles 12 and then condenses into a thin film. For current evaporation devices, owing to unbalanced pressure of vapor in a chamber of the evaporator 20 due to a bar shape of the evaporator 20, an evaporation rate of organic molecules from different nozzles 12 is inconsistent and thus results in thickness nonuniformity of a coating film on the substrate. In fabricating large-sized OLEDs, the above deficiencies are particularly notable.

Therefore, it is required to provide an evaporation device in order to solve the above problems regarding the thickness nonuniformity of a coating film.

### SUMMARY

A technical problem is that, owing to unbalanced pressure of vapor in the chamber of the evaporator due to a bar shape of the evaporator, an evaporation rate of organic molecules from different nozzles is inconsistent and thus results in thickness nonuniformity of a coating film on the substrate. In fabricating large-size OLEDs, the above deficiencies are particularly notable.

The object of the present disclosure is to provide an evaporation device to control an evaporation rate of organic molecules and effectively improve thickness uniformity of a coating film.

In order to realize the above object, the present disclosure provides an evaporation device, including:

an evaporator for containing and vaporing an evaporation material;

a gas chamber for collecting vapor from the evaporation material, wherein a plurality of nozzles are disposed at an interval and on a side face of the gas chamber, and wherein the plurality of nozzles are linearly evenly arranged at an equal distance from each other and on the side face of the gas chamber;

a plurality of pipelines disposed at an interval and between the evaporator and the gas chamber, wherein two ends of each of the plurality of pipelines communicate with the evaporator and the gas chamber respectively;

a heating unit disposed at peripheries of the evaporator, the gas chamber, and the plurality of pipelines and configured to heat the evaporator, the gas chamber, and the plurality of pipelines; and

a controller electrically connected to the heating unit and configured to control a temperature of the heating unit in order that the temperature and the pressure inside the gas chamber retain predetermined values respectively.

In some embodiments, the heating unit includes a first heating element disposed at a periphery of the evaporator and electrically connected to the controller.

In some embodiments, the heating unit further includes at least one second heating element disposed at peripheries of the plurality of pipelines and electrically connected to the controller.

In some embodiments, the heating unit further includes a third heating element disposed at a periphery of the gas chamber and electrically connected to the controller.

In some embodiments, the evaporator is a crucible.

In some embodiments, the gas chamber is a bar box.

In some embodiments, the heating unit is a heating wire or a heating plate.

In order to realize the above object, the present disclosure provides an evaporation device, including: an evaporator for containing and vaporing an evaporation material; a gas chamber for collecting vapor from the evaporation material, wherein a plurality of nozzles are disposed at an interval and on a side face of the gas chamber; a plurality of pipelines disposed between the evaporator and the gas chamber, wherein two ends of each of the plurality of pipelines communicate with the evaporator and the gas chamber respectively; a heating unit disposed at peripheries of the evaporator, the gas chamber, and the plurality of pipelines and configured to heat the evaporator, the gas chamber, and the plurality of pipelines; and a controller electrically connected to the heating unit and configured to control a temperature of the heating unit in order that the temperature and the pressure inside the gas chamber retain predetermined values respectively.

In some embodiments, the heating unit includes a first heating element disposed at a periphery of the evaporator and electrically connected to the controller.

In some embodiments, the heating unit further includes at least one second heating element disposed at peripheries of the plurality of pipelines and electrically connected to the controller.

In some embodiments, the heating unit further includes a third heating element disposed at a periphery of the gas chamber and electrically connected to the controller.

In some embodiments, the evaporator is a crucible.

In some embodiments, the plurality of pipelines are disposed at an interval and between the evaporator and the gas chamber.

In some embodiments, the gas chamber is a bar box.

In some embodiments, the heating unit is a heating wire or a heating plate.

In some embodiments, the plurality of nozzles are linearly evenly arranged at an equal distance from each other and on the side face of the gas chamber.

The beneficial effect of the present disclosure is that, an evaporation device is provided to control an evaporation rate of organic molecules and effectively improve thickness uniformity of a coating film.

### BRIEF DESCRIPTION OF DRAWINGS

To ensure the features and the technical content of the disclosure are more apparent and easier to understand, please refer to the explanation and the accompanying drawings of the disclosure as follows. However, the accompanying drawings are merely for reference without limiting the disclosure.

FIG. 1 is a schematic structural diagram of a conventional evaporation device.

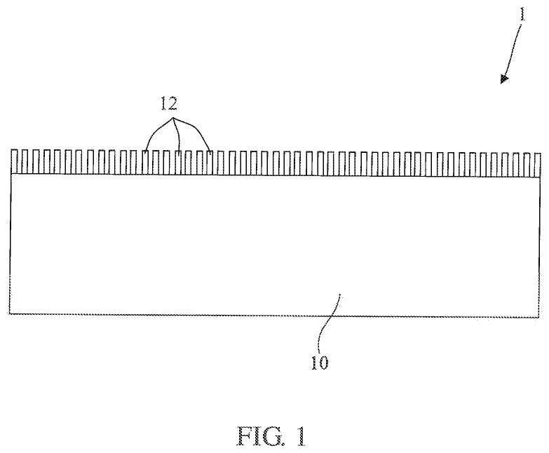

FIG. 2 is a schematic structural diagram of an evaporation device according to an embodiment of the present disclosure.

### DETAILED DESCRIPTION OF EMBODIMENTS

To ensure the objects, the technical solutions, and the effects of the disclosure are clearer and more specific, the disclosure will be explained in conjunction with the accompanying drawings in detail further below. It should be understood that the embodiments described herein are merely a part of the embodiments of the present disclosure instead of all of the embodiments and not used to limit the disclosure.

Please refer to FIG, 2, which is a schematic structural diagram of an evaporation device according to an embodiment of the present disclosure. An evaporation device 2 includes an evaporator 20, a gas chamber 22, pipelines 24, a heating unit 26, and a controller 28. The evaporator 20 is used for containing and vaporing an evaporation material. In some embodiments, the evaporator 20 may be a crucible, and the evaporation material is a kind of organic materials.

The gas chamber 22 is used for collecting vapor from the evaporation material. A plurality of nozzles 220 are disposed at an interval and on a side face of the gas chamber 22. In some embodiments, the gas chamber 22 is a bar box. Furthermore, the plurality of nozzles 220, linearly evenly arranged at an equal distance from each other and on the side face of the gas chamber 22, are used for spraying the vapor.

A plurality of pipelines 24 are disposed between the evaporator 20 and the gas chamber 22, and two ends of each pipeline 24 communicate with the evaporator 20 and the gas chamber 22 respectively In an embodiment of the present disclosure, the plurality of pipelines 24 are disposed at an interval and between the evaporator 20 and the gas chamber 22.

The heating unit 26 is disposed at peripheries of the evaporator 20, the gas chamber 22, and the plurality of pipelines 24 and configured to heat the evaporator 20, the gas chamber 22, and the plurality of pipelines 24. In some embodiments, the heating unit 26 is a heating wire or a heating plate.

The controller 28 is electrically connected to the heating unit 26 and configured to control a temperature of the heating unit 26 in order that the temperature and the pressure inside the gas chamber 22 retain predetermined values respectively. In some embodiments, the predetermined values depend on a required thickness of a coating film.

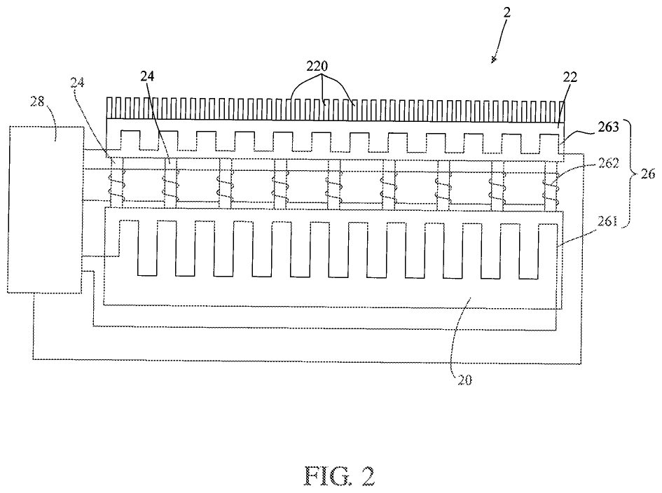

Continuing to refer to FIG. 2, in an embodiment of the present disclosure, the heating unit 26 includes a first heating element 261 disposed at a periphery of the evaporator 20 and electrically connected to the controller 28. The heating unit 26 further includes at least one second heating element 262 disposed at peripheries of the plurality of pipelines 24 and electrically connected to the controller 28. Further, the heating unit 26 also includes a third heating element 263 disposed at a periphery of the gas chamber 22 and electrically connected to the controller 28. Specifically, in the embodiment of FIG. 2, the first heating element 261, the second heating element 262, and the third heating element 263 are, but not limited to, heating wires. Also, the first heating element 261, the second heating element 262, and the third heating element 263 may be heating plates or any other types of heating elements.

When the first heating element 261 heats the evaporation material in the evaporator 20, temperatures of vapor in different parts of the evaporator 20 are not identical. Thus, the controller 28 controls temperatures of different second heating elements 262 to achieve consistency in temperature of vapor from each pipeline 24 while vapor passes through the plurality of pipelines 24. For example, controlling temperatures of the second heating elements 262 around the pipelines 24 located at two ends of the evaporator 20 to be higher than temperatures of the second heating elements 262 around the pipelines 24 located in the middle of the evaporator 20. In addition, the vapor which has passed through the plurality of pipelines 24 is mixed in the gas chamber 22 to balance gas pressure, and then the controller 28 controls a temperature of the third heating element 263 to make vapor maintain its status of gas molecules and to make the pressure inside the gas chamber 22 retain a predetermined value.

According to the ideal gas equation, i.e., PV=nRT, a number of gas molecules “n” or volume of a gas “V” will be constant while a pressure “P” and a temperature “T” remain unchanged. In the present disclosure, the temperature and the pressure in the gas chamber 22 still remain unchanged so that a rate or a number of organic molecules of vapor sprayed from the plurality of nozzles 220 is equal, and thus a thickness of a coating film is identical, that is, the object of uniformity of evaporation is realized.

In conclusion, the present disclosure provides an evaporation device mainly by controlling a temperature of a heating unit through a controller, and thus an evaporation rate of organic molecules is controlled so that the object of improving thickness uniformity of a coating film is realized.

It should be understood that the application of the present disclosure is not limited by the foregoing examples. A person of ordinary skill in the art is able to make modifications or changes based on the foregoing description, and all of these modifications and changes are within the scope of the appended claims of the present disclosure.

The industrial applicability of the present disclosure is that, an evaporation device is mainly provided by controlling a temperature of a heating unit through a controller, and thus an evaporation rate of organic molecules is controlled so that the object of improving thickness uniformity of a coating film is realized.

What is claimed is:

1. An evaporation device, comprising:
an evaporator for containing and vaporing an evaporation material;
a gas chamber for collecting vapor from the evaporation material, wherein a plurality of nozzles are disposed at an interval and on a side face of the gas chamber, and wherein the plurality of nozzles are linearly evenly arranged at an equal distance from each other and on the side face of the gas chamber;
a plurality of pipelines disposed at an interval and between the evaporator and the gas chamber, wherein two ends of each of the plurality of pipelines communicate with the evaporator and the gas chamber respectively;
a heating unit disposed at peripheries of the evaporator, the gas chamber, and the plurality of pipelines and configured to heat the evaporator, the gas chamber, and the plurality of pipelines; and
a controller electrically connected to the heating unit and configured to control a temperature of the heating unit in order that the temperature and the pressure inside the gas chamber retain predetermined values respectively.

2. The evaporation device according to claim 1, wherein the heating unit comprises a first heating element disposed at a periphery of the evaporator and electrically connected to the controller.

3. The evaporation device according to claim 2, wherein the heating unit further comprises at least one second heating element disposed at peripheries of the plurality of pipelines and electrically connected to the controller.

4. The evaporation device according to claim 3, wherein the heating unit further comprises a third heating element disposed at a periphery of the gas chamber and electrically connected to the controller.

5. The evaporation device according to claim 1, wherein the evaporator is a crucible.

6. The evaporation device according to claim 1, wherein the gas chamber is a bar box.

7. The evaporation device according to claim 1, wherein the heating unit is a heating wire or a heating plate.

8. An evaporation device, comprising:
an evaporator for containing and vaporing an evaporation material;
a gas chamber for collecting vapor from the evaporation material, wherein a plurality of nozzles are disposed at an interval and on a side face of the gas chamber;
a plurality of pipelines disposed between the evaporator and the gas chamber, wherein two ends of each of the plurality of pipelines communicate with the evaporator and the gas chamber respectively;
a heating unit disposed at peripheries of the evaporator, the gas chamber, and the plurality of pipelines and configured to heat the evaporator, the gas chamber, and the plurality of pipelines; and
a controller electrically connected to the heating unit and configured to control a temperature of the heating unit in order that the temperature and the pressure inside the gas chamber retain predetermined values respectively.

9. The evaporation device according to claim 8, wherein the heating unit comprises a first heating element disposed at a periphery of the evaporator and electrically connected to the controller.

10. The evaporation device according to claim 9, wherein the heating unit further comprises at least one second heating element disposed at peripheries of the plurality of pipelines and electrically connected to the controller.

11. The evaporation device according to claim 10, wherein the heating unit further comprises a third heating element disposed at a periphery of the gas chamber and electrically connected to the controller.

12. The evaporation device according to claim 8, wherein the evaporator is a crucible.

13. The evaporation device according to claim 8, wherein the plurality of pipelines are disposed at an interval and between the evaporator and the gas chamber.

14. The evaporation device according to claim 8, wherein the gas chamber is a bar box.

15. The evaporation device according to claim 8, wherein the heating unit is a heating wire or a heating plate.

16. The evaporation device according to claim 8, wherein the plurality of nozzles are linearly evenly arranged at an equal distance from each other and on the side face of the gas chamber.
